(19) United States
(12) Patent Application Publication
(10) Pub. No.: US 2019/0104639 A1
(43) Pub. Date: Apr. 4, 2019

(54) COOLING MODULE WITH MULTIPLE PARALLEL BLOWERS

(71) Applicant: HENKEL IP & HOLDING GMBH, Duesseldorf (DE)

(72) Inventors: John F. O'Connor, New Hartford, CT (US); Roger B. Dickinson, Torrington, CT (US)

(21) Appl. No.: 16/207,839

(22) Filed: Dec. 3, 2018

Related U.S. Application Data
(63) Continuation of application No. 15/191,771, filed on Jun. 24, 2016, now abandoned.
Application No. 15/191,771 is a continuation of application No. 13/163,385, filed on Jun. 17, 2011, now abandoned.
(60) Provisional application No. 61/356,374, filed on Jun. 18, 2010.

(51) Int. Cl. H05K 7/20; F04D 29/42; F04D 29/28; F04D 27/00; F04D 17/16; F04D 25/02; F04D 25/16; F04D 25/08

(52) U.S. Cl. CPC H05K 7/20172; F04D 29/4233; F04D 29/281; F04D 27/004; F04D 25/08; F04D 25/02; F04D 25/166; F04D 17/16

(57) ABSTRACT

A cooling fan module for motivating air flow through an electronics chassis includes an enclosure having an air inlet through which cooling air flow is motivated by at least two centrifugal blowers disposed within the enclosure. The centrifugal blowers operate in parallel to motivate the cooling air flow along a first direction vector, while the respective axes of rotation of the centrifugal blower impellers are in substantial axial alignment with one another, and parallel to the first direction vector.

### CROSS-REFERENCE TO RELATED APPLICATIONS

This application claims priority to U.S. provisional Patent Application Ser. No. 61/356,374, filed on Jun. 18, 2010 and entitled “Cooling Module with Multiple Parallel Blowers”, and to U.S. non-provisional patent application Ser. No. 13/163,385, filed Jun. 17, 2011 and Ser. No. 15/191,771, filed Jun. 24, 2016 the contents of which are being incorporated herein in their entirety.

### TECHNICAL FIELD OF THE INVENTION

The present invention relates to cooling systems generally, and more particularly to a cooling fan module for motivating cooling air flow through an electronics chassis, wherein the cooling fan module is substantially more efficient and produces substantially less noise than conventional cooling fan arrangements, without requiring increased volume.

### BACKGROUND OF THE INVENTION

This invention relates to a module, commonly referred to as a fan tray, designed to provide cooling flow to an electronics apparatus. Specifically, the module contains a parallel flow arrangement of centrifugal blowers. The present arrangement optimizes performance of the module by employing high efficiency forward curved centrifugal blowers arranged in a specific relationship axially in line with the primary air inlet to the module. The module is especially well suited for cooling of telecommunication routers and similar high powered, densely populated electronic equipment.

Designers of electronic equipment have become increasingly challenged to provide high-power devices in relatively small packages. These devices require compact and highly efficient cooling systems. A typical cooling system involves moving air across one or more printed circuit cards. The flow path layout, type of air moving device, and how well it is integrated into the system, are all key elements in achieving the desired performance in a small package size with low noise.

One such electronic device is the telecommunications router. The desire to make them more powerful, yet compact in size, leaves little space for cooling system components necessary to address ever-increasing heat loads. Conventional system designs often employ fans that are not well matched to the system pressures, or do not move air efficiently within the space constraints, and result in unacceptable noise, and relatively large power consumption.

Design efforts to date typically use multiple axial fans arranged in parallel in a “tray”, refer to FIGS. 2a and 2b. The fans either push cool air through a chassis or pull warm air out of a chassis. Sometimes two trays are arranged in series as a push and pull-through system. Relatively high aerodynamic efficiencies can be achieved with this type of air mover, but unfortunately they require high rotational speeds that typically result in unacceptable acoustic signatures. Alternate arrangements include “Backward Curved” (BC) centrifugal type blowers pulling air through a chassis, refer to FIGS. 3a and 3b. These fans typically have similar acoustic performance to axial fans, and they require relatively large diffusers to realize acceptable aerodynamic efficiency. Typical packaging constraints don't allow for proper diffusers, resulting in poor system efficiencies, and compromised acoustics.

In still further conventional arrangements, “Forward Curved” (FC) centrifugal type blowers may be arranged in a module for pulling air through a chassis, but are typically arranged with the blower inlets perpendicular to, or otherwise not in axially aligned relationship with, the air inlet to the fan module, refer to FIGS. 4a and 4b. Such arrangements do not provide the desired efficiencies and acoustics of the present invention.

### SUMMARY OF THE INVENTION

By means of the present invention, electronics applications with high-density component populations may be efficiently and effectively cooled with a low-volume cooling module. The specific arrangement of forward-curved centrifugal blowers of the present invention facilitates the creation of a cooling module of low physical volume that nevertheless generates desired levels of air movement power at substantially reduced noise. Electronics chassis manufacturers, therefore, are able to achieve high performance within small-volume packages.

In one embodiment, a cooling fan module of the present invention includes an enclosure having an air inlet through which air flow is drawn from an associated electronics chassis. At least two centrifugal blowers may be disposed within the enclosure, and in parallel motivate the air flow along a first direction vector through the air inlet. Each of the centrifugal blowers include a scroll housing defining an air inlet and an air discharge, a forward-curved impeller having a diameter dimension and defining an axis of rotation, and a motor for rotation of the impeller about the axis. The axis of rotation extends through the housing air inlet and substantially parallel to the first direction vector. The respective axes of rotation of the centrifugal blower impellers may be in substantial axial alignment with one another.

In another embodiment, a cooling fan module of the present invention includes an enclosure having an air inlet through which air flow is drawn from an associated electronic chassis, and a first set of a plurality of centrifugal blowers disposed within the enclosure. The first set of centrifugal blowers in parallel motivate air flow along a first direction vector into the enclosure. Each of the centrifugal blowers of the first set includes a scroll housing defining an air inlet and an air discharge, a forward-curved impeller having a diameter dimension and defining an axis of rotation, and a motor for rotation of the impeller about the axis. The axis of rotation extends through the housing air inlet substantially parallel to the first direction vector. The respective axes of rotation of the centrifugal blower impellers may be in substantial axial alignment with one another. The cooling fan module may further include a second set of one or more blowers disposed within the enclosure and motivating the air flow along a second direction vector into the enclosure, wherein the second direction vector is substantially perpendicular to the first direction vector.

The accompanying drawings, which are incorporated in and constitute a portion of this specification, illustrate embodiments of the invention and, together with the detailed description, serve to further explain the invention. The embodiments illustrated herein are presently preferred; however, it should be understood, that the invention is not limited to the precise arrangements and instrumentalities shown. For a fuller understanding of the nature and advantages of the invention, reference should be made to the detailed description in conjunction with the accompanying drawings.

### DESCRIPTION OF THE DRAWINGS OF THE PREFERRED EMBODIMENTS

In the various figures, which are not necessarily drawn to scale, like numerals throughout the figures identify substantially similar components.

FIG. 1a is a partial cut away view of a cooling fan module of the present invention;

FIG. 1b is a schematic illustration of the cooling fan module of FIG. 1 in combination with an electronics chassis;

FIG. 2a is a partial cut away view of a cooling fan module of the prior art;

FIG. 2b is a schematic illustration of cooling fan modules as illustrated in FIG. 2a in combination with an electronics chassis;

FIG. 3a is a partial cut away view of a cooling fan module of the prior art;

FIG. 3b is a schematic illustration of the cooling fan module of FIG. 3a in combination with an electronics chassis;

FIG. 4a is a partial cut away view of a cooling fan module of the prior art;

FIG. 4b is a schematic illustration of the cooling fan module of FIG. 4a in combination with an electronics chassis;

FIG. 5a is a partial cut away view of a cooling fan module of the present invention;

FIG. 5b is a schematic illustration of the cooling fan module of FIG. 5a in combination with an electronics chassis; and

FIG. 6 is a schematic illustration of a cooling fan module of the present invention in combination with an electronics chassis.

### DETAILED DESCRIPTION OF THE INVENTION

The following description provides detail of various embodiments of the invention, one or more examples of which are set forth below. Each of these embodiments are provided by way of explanation of the invention, and not intended to be a limitation of the invention. Further, those skilled in the art will appreciate that various modifications and variations may be made in the present invention without departing from the scope or spirit of the invention. By way of example, those skilled in the art will recognize that features illustrated or described as part of one embodiment, may be used in another embodiment to yield a still further embodiment. Thus, it is intended that the present invention also cover such modifications and variations that come within the scope of the appended claims and their equivalents.

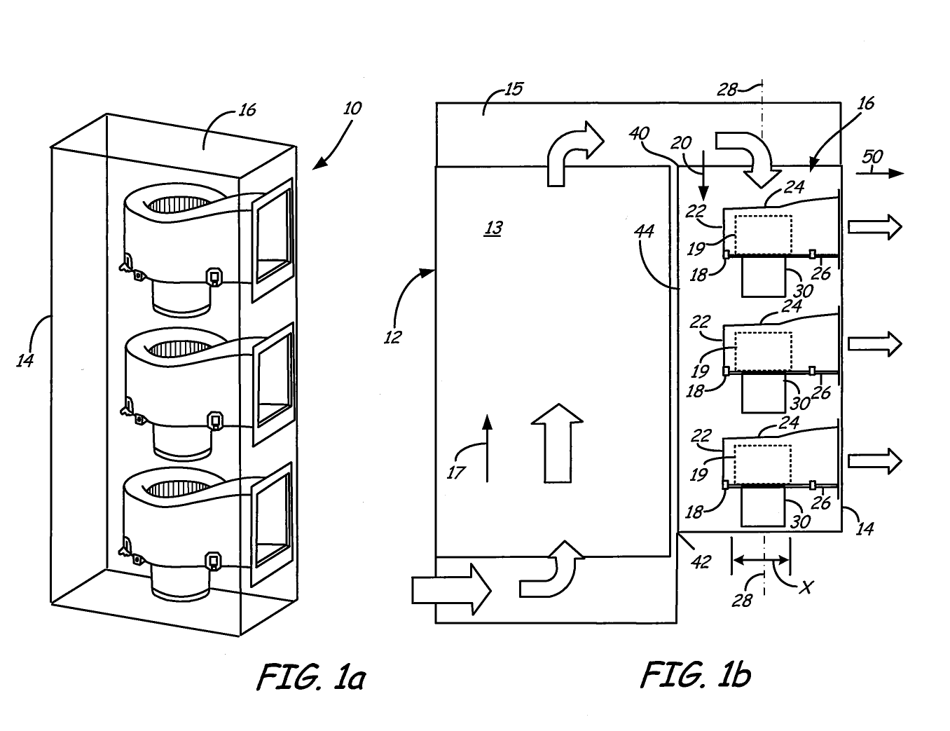

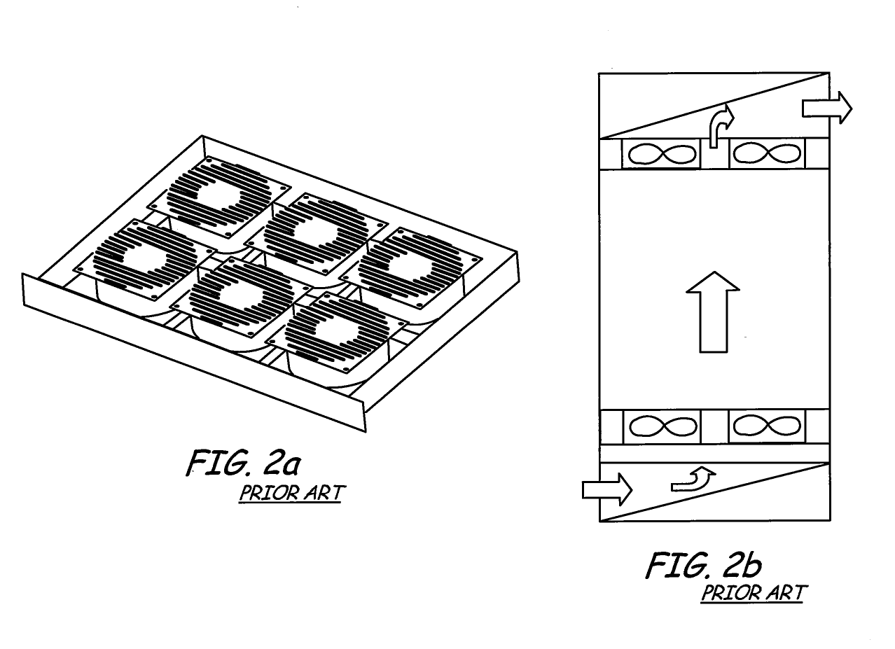

The present invention addresses the efficiency and noise issues outlined above. The preferred embodiment includes an air mover module set up to motivate air through an electronics chassis, wherein the module employs multiple forward curved (FC) centrifugal blowers arranged in a parallel flow configuration, and the blower air inlets are arranged axially in-line with module primary inlet, refer to FIGS. 1a & 1b. This arrangement provides high efficiency and low noise in a relatively small packaging volume. The present invention uses several features, in combination, to achieve high performance within the constraints outlined.

As illustrated in FIGS. 1a and 1b, a cooling fan module 10 may be arranged to pull air flow through an electronic chassis 12 to cool electronics disposed in the chassis 12. Example electronics chassis 12 that may contain electronic components in need of the presently proposed cooling include telecommunication routers, servers, and power supply units. Cooling fan module 10 includes an enclosure 14 having an air inlet 16 though which air flow (represented by arrows) is drawn from electronics chassis 12. In the illustrated embodiment, cooling air flow is motivated through an interior chamber 13 of chassis 12, and through a plenum 15 to reach air inlet 16 of cooling fan module 10. It is contemplated that module 10 may be secured to or integrally formed with chassis 12 in any suitable manner to achieve cooling air flow motivation through inlet 16. Specifically, the arrangements of the present invention need not include plenum 15, and may position module 10 directly in line with initial air flow direction 17.

Module 10 further includes a plurality of centrifugal blowers 18 disposed within enclosure 14 and in parallel motivating the air flow generally along a first direction vector 20 through air inlet 16. Centrifugal blowers 18 motivate the air flow in parallel by each individually acting upon air flow entering air inlet 16 to therefore direct air flow along first direction vector 20. In addition, centrifugal blowers 18 motivate the air flow in parallel by receiving air to their respective inlets that is sourced directly from air passing thorough chassis 12, and not as exhaust from an “upstream” blower. As illustrated in FIG. 1b, discharge from each centrifugal blower 18 exits enclosure 14, and is therefore not fed to a subsequent blower 18. In this manner, centrifugal blowers 18 are considered to motivate the air flow “in parallel.”

Each of centrifugal blowers 18 includes a scroll housing 22 which defines an air inlet 24 and an air discharge 26. Centrifugal blowers 18 further include a forward-curved impeller 19 having a diameter dimension “x”, and defining an axis of rotation 28 which extends through housing air inlet 24 and substantially parallel to first direction vector 20. The centrifugal blowers 18 each further include a motor 30 for rotation of the respective impellers 19 about axis 28. As illustrated in FIG. 1b, the respective axes of rotation 28 of the centrifugal blower impellers are in substantial axial alignment with one another.

The arrangement described above has been found to provide surprisingly enhanced aerodynamic efficiency for each blower 18, such that total power input to motivate a desired air flow may be reduced. In addition, the surprising efficiency of the proposed arrangement reduces sound emissions, which is also a beneficial operating characteristic of the fan modules of the present invention.

In further description of module 10, enclosure 14 includes first and second ends 40, 42 separated by one or more side walls 44. Air inlet 16 may be disposed at first end 40 of enclosure 14. In the illustrated embodiment, the air inlets 24 of each of centrifugal blowers 18 may be arranged in enclosure 14 in facing relationship with enclosure air inlet 16. In other embodiments, however, one or more of such centrifugal blower air inlets 24 may be facing substantially away from enclosure air inlet 16.

As further illustrated in FIG. 1b, the respective air discharges 26 of centrifugal blowers 18 may be arranged to emit air along a second direction vector 50 which is substantially perpendicular to first direction vector 20.

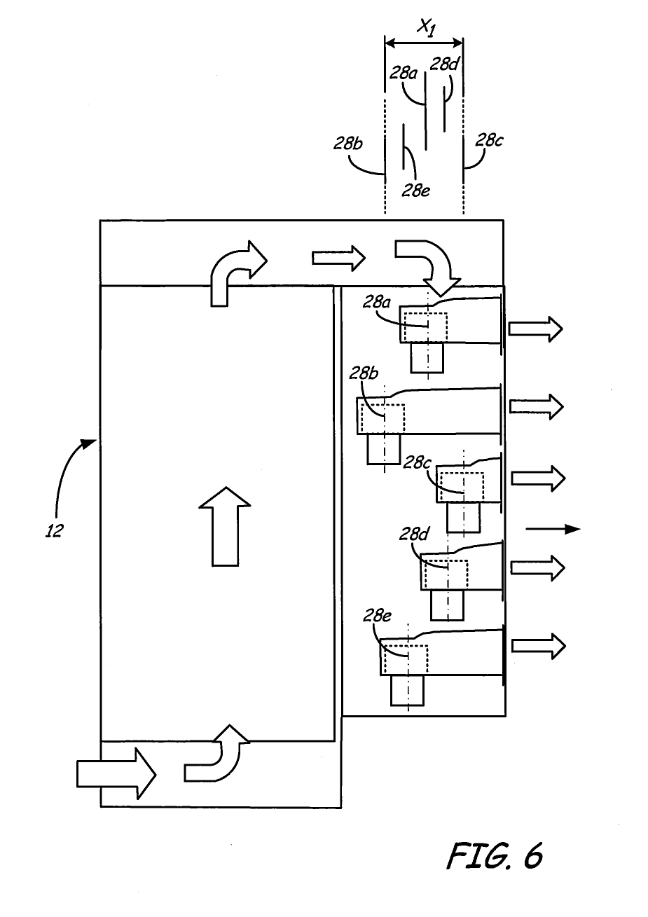

For the purposes hereof, the term “axial alignment” is intended to mean that the respective axes of rotation of the centrifugal blower impellers are arranged in precise axial alignment, or in close substantially parallel proximity thereto. The term “axial alignment” may therefore include respective axes of rotation 28 which are substantially parallel to the remaining axes of rotation 28, and are spaced apart by no more than a dimension equal to diameter dimension “x” of the centrifugal blower impeller 19. An example arrangement of centrifugal blowers which are in “axial alignment” for the purposes hereof is illustrated in FIG. 6. As shown therein, each of the respective axes of rotation 28a-28e are within a dimension X₁ that is substantially equal to a diameter dimension “x” of the centrifugal blower impeller.

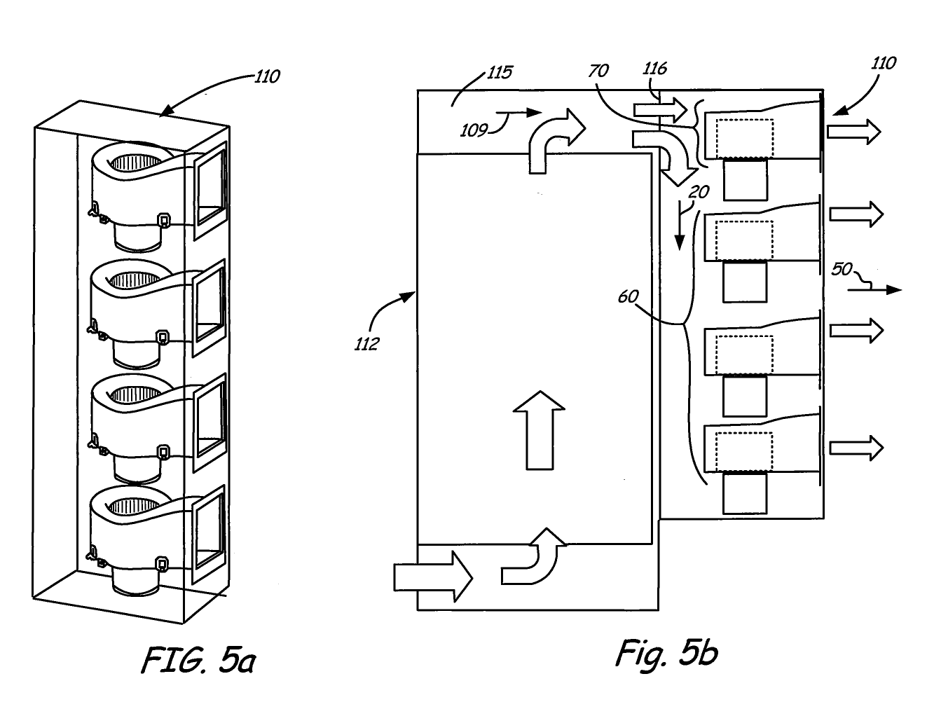

A further embodiment of the present invention is illustrated in FIGS. 5a and 5b, wherein a first set of a plurality of centrifugal blowers 60 is arranged as described above, and wherein a second set of one or more blowers 70 may be arranged and positioned to motivate the air flow along a direction substantially parallel to second direction vector 50, or substantially perpendicular to first direction vector 20. Thus, in the embodiment illustrated in FIGS. 5a and 5b, module 110 includes first and second sets of blowers, wherein a first set motivates air flow into module 110 substantially along first direction vector 20, while a second set of blowers 70 motivates air flow into module 110 along second direction vector 50. In this embodiment, first set of centrifugal blowers 60 includes a plurality of centrifugal blowers, and second set of blowers 70 includes one or more blowers. In all other respects, the blowers of second set 70 may be similar to the centrifugal blowers 18 of first set 60. In other embodiments, however, the blowers of second set 70 may be structurally and functionally distinct from first set of blowers 60, including reverse-curved centrifugal blowers, axial blowers, and other designs deemed suitable for the respective application.

In the embodiment illustrated in FIG. 5b, plenum 115 may be arranged to intermediately direct cooling air flow to module inlet 116 along a flow direction 109 that is substantially parallel to second direction vector 50. It is also to be understood that the illustrations of FIGS. 1b and 5b are schematic only, and merely represent the functional interaction of modules 10, 110, with an associated electronics chassis 12, 112.

The fan aerodynamic efficiency is critical to provide the required flow rate with relatively low power input. This is necessary to keep the drive motor dimensions as compact as possible. Motor axial length should be minimized to maintain the low overall height of the system and optimum air entry condition for the downstream blower.

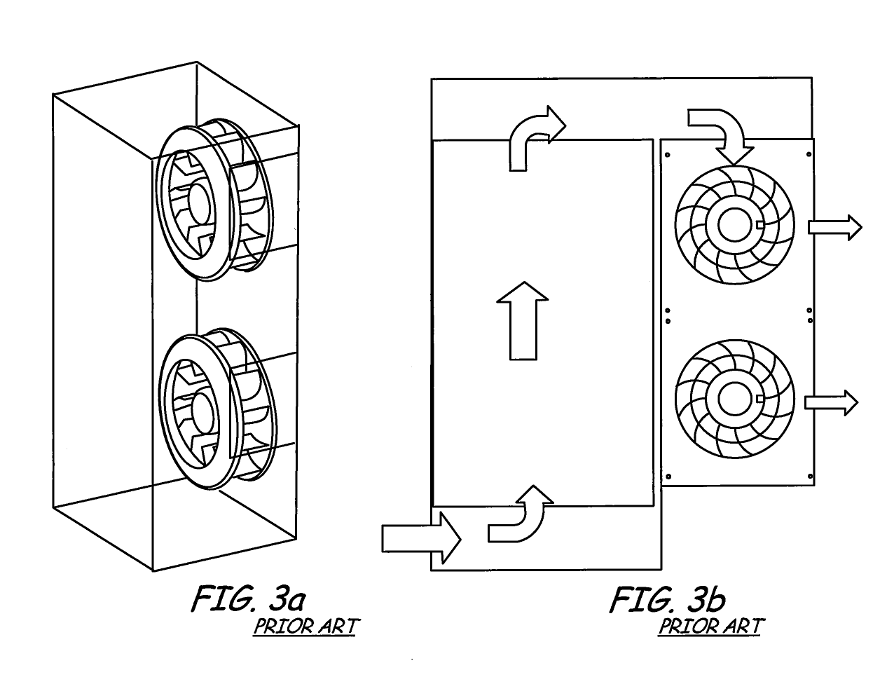

Table 1 represents actual performance measured on an example embodiment module arrangement as described in FIGS. 1a and 1b, compared to a module arrangement as described in “prior art” FIGS. 3a and 3b.

TABLE 1

| | Example | | | | Delta from |
|---|---|---|---|---|---|
| | Embodiment | | Prior Art | | Example |
| | (FIG. 1) | | (FIG. 3) | | Embodiment |
| Air Power output | 41 | watts | 41 | watts | — |
| Tip Speed | 2729 | ft/min | 5739 | ft/min | +110% |
| Line Power input | 195 | watts | 290 | watts | +49% |
| Sound Power | 75 | dBA | 86 | dBA | +11 dBA |

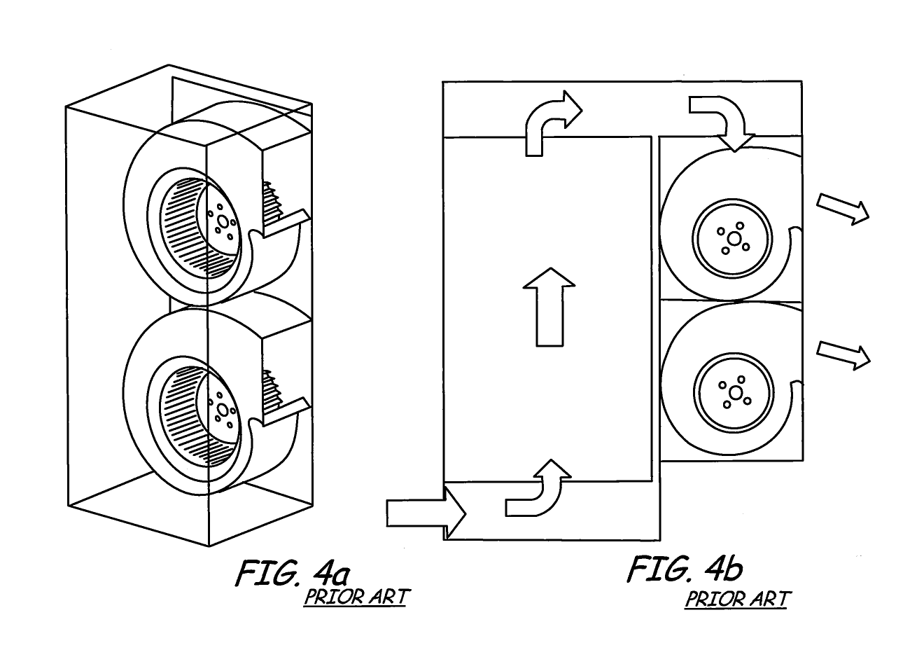

Table 2 represents actual performance measured on an example embodiment module design as described in FIGS. 1a and 1b, compared to a module design as described in “prior art” FIGS. 4a and 4b. Note this data was measured on a system that is approximately ten times larger than the Table 1 system with respect to heat load, demonstrating the scaling capability of the technology.

TABLE 2

| | Example | | | | Delta from |
|---|---|---|---|---|---|
| | Embodiment | | Prior Art | | Example |
| | (FIG. 1) | | (FIG. 4) | | Embodiment |
| Air Power output | 402 | watts | 402 | watts | — |
| Tip Speed | 5786 | ft/min | 6597 | ft/min | +14% |
| Line Power input | 2175 | watts | 3500 | watts | +61% |

| | | | |
|---|---|---|---|
| Sound Power | NA | NA | NA |

These and various other aspects and features of the invention are described with the intent to be illustrative, and not restrictive. This invention has been described herein with detail in order to comply with the patent statutes and to provide those skilled in the art with information needed to apply the novel principles and to construct and use such specialized components as are required. It is to be understood, however, that the invention can be carried out by specifically different constructions, and that various modifications, both as to the construction and operating procedures, can be accomplished without departing from the scope of the invention. Further, in the appended claims, the transitional terms comprising and including are used in the open ended sense in that elements in addition to those enumerated may also be present. Other examples will be apparent to those of skill in the art upon reviewing this document.

1. A cooling fan module for motivating air flow through an electronics chassis, said module comprising:
an enclosure having an air inlet through which the air flow is drawn from said electronics chassis;
at least two centrifugal blowers disposed within said enclosure and in parallel motivating the air flow along a first direction vector through said air inlet, each of said centrifugal blowers comprising:
(i) a scroll housing defining an air inlet and an air discharge;
(ii) a forward-curved impeller having a diameter dimension, and defining an axis of rotation, said axis extending through said housing air inlet and substantially parallel to said first direction vector; and
(iii) a motor for rotation of said impeller about said axis,
wherein said respective axes of rotation of said centrifugal blower impellers are in substantial axial alignment with one another.

2. A cooling fan module as in claim 1 wherein said enclosure includes first and second ends separated by one or more side walls, and said air inlet being disposed at said first end.

3. A cooling fan module as in claim 1 wherein said centrifugal blowers are all disposed on a first side of a mid-plane of the electronics chassis.

4. A cooling fan module as in claim 1 wherein said air inlets of each of said centrifugal blowers are arranged in said enclosure in facing relationship with said enclosure air inlet.

5. A cooling fan module as in claim 1 wherein said motor of said centrifugal blowers is variable speed.

6. A cooling fan module as in claim 5 wherein said motor of each of said centrifugal blowers is independently controlled.

7. A cooling fan module as in claim 1 wherein said air discharges of said centrifugal blowers are arranged to emit air along a second direction vector which is substantially perpendicular to said first direction vector.

8. A cooling fan module as in claim 1 wherein said scroll housing of each of said centrifugal blowers includes a single air inlet.

9. A cooling fan module as in claim 1 wherein said scroll housing of each of said centrifugal blowers expands both radially and axially from proximate to a cutoff to said air discharge.

10. A cooling fan module as in claim 1 wherein said centrifugal blowers are axially spaced apart along said axis by a first distance of about one half of said impeller diameter dimension.

11. A cooling fan module for pulling air flow through an electronics chassis, said module comprising:
an enclosure having an air inlet through which the air flow is drawn from said electronics chassis;
a first set of a plurality of centrifugal blowers disposed within said enclosure and in parallel motivating the air flow along a first direction vector into said enclosure, each of said centrifugal blowers of said first set comprising;
(i) a scroll housing defining an air inlet and an air discharge;
(ii) a forward-curved impeller having a diameter dimension, and defining an axis of rotation, said axis extending through said housing air inlet and substantially parallel to said first direction vector; and
(iii) a motor for rotation of said impeller about said axis,
wherein said respective axes of rotation of said centrifugal blower impellers are in substantial axial alignment with one another;
a second set of one or more blowers disposed within said enclosure and motivating the air flow along a second direction vector into said enclosure, said second direction vector being substantially perpendicular to said first direction vector.

12. A cooling fan module as in claim 11 wherein said second set of one or more blowers is disposed proximate to said enclosure air inlet.
